(19) United States
(12) Patent Application Publication
(10) Pub. No.: US 2018/0016156 A1
(43) Pub. Date: Jan. 18, 2018

(54) PRODUCTION OF CRYSTALLIZED COBALT (II) CHLORIDE HEXAHYDRATE

(71) Applicants: Morteza Enhessari, Naragh (IR); Ali Salehabadi, Kashan (IR); Keyvan Ozaee, Tehran (IR)

(72) Inventors: Morteza Enhessari, Naragh (IR); Ali Salehabadi, Kashan (IR); Keyvan Ozaee, Tehran (IR)

(21) Appl. No.: 15/716,470

(22) Filed: Sep. 26, 2017

Related U.S. Application Data
(60) Provisional application No. 62/403,216, filed on Oct. 3, 2016.

(51) Int. Cl. C01G 51/08; C30B 25/14; B01D 9/00; B01D 1/00; C22B 3/00; B01D 24/02; C30B 25/18; C30B 7/08

(52) U.S. Cl. CPC C01G 51/085; C30B 25/186; C30B 25/14; C30B 7/08; B01D 1/0011; C22B 23/0423; B01D 24/02; B01D 9/0018; B01D 2259/122

(57) ABSTRACT

A method for production of crystallized Cobalt (II) Chloride hexahydrate is disclosed, and an implementation includes preparing a first cobalt (II) chloride solution, separating impurities from the first cobalt (II) chloride solution to obtain a second cobalt (II) chloride solution, concentrating the second cobalt (II) chloride solution, cooling the concentrated second cobalt (II) chloride solution, and injecting CO₂ gas into the cooled concentrated second cobalt (II) chloride solution at an atmospheric pressure in order for Cobalt (II) Chloride hexahydrate crystals to form in the cooled concentrated second cobalt (II) chloride solution.

### CROSS REFERENCE TO RELATED APPLICATION

This application claims the benefit of priority from pending U.S. Provisional Patent Application Ser. No. 62/403,216, filed on Oct. 3, 2016, and entitled “A PROCESS FOR CRYSTALLIZATION OF COBALT (II) CHLORIDE HEXAHYDRATE,” which is incorporated herein by reference in its entirety.

### SPONSORSHIP STATEMENT

This application has been sponsored by Iran Patent Center, which does not have any rights in this application.

### TECHNICAL FIELD

The present disclosure generally relates to crystallization methods, and particularly to crystallization methods for producing crystallized cobalt (II) chloride hexahydrate.

### BACKGROUND

Cobalt (II) chloride is an inorganic compound that can be supplied as cobalt (II) chloride hexahydrate (CoCl₂.6H₂O). CoCl₂.6H₂O is purple while the anhydrous form of cobalt (II) chloride is sky blue. Because of this notable color change during hydration/dehydration reaction of cobalt (II) chloride, it can be used as an indicator for water in desiccants. Cobalt (II) chloride may also be used as any among an analytical agent, a ceramic coloring agent, a paint drier, and a catalyst.

Cobalt (II) chloride hexahydrate may be prepared by methods such as basic cobalt carbonate conversion method, basic cobalt hydroxide conversion method, or via substitution reaction between metallic cobalt and hydrochloride acid. However, preparation of cobalt (II) chloride hexahydrate via these methods may be associated with various deficiencies. For example, when using the basic cobalt carbonate conversion method there may be an accompanying formation of cobalt nitrate, which may make purifying the final product difficult. As another example, the basic cobalt hydroxide conversion method may have an accompanying formation of byproducts, which may decrease the yield of the method; and slow hydrogen ion substitution in the substitution reaction between metallic cobalt and hydrochloride acid, which may lead to a slow reaction. Furthermore, due to the presence of hydrogen gas, the substitution reaction between metallic cobalt and hydrochloride acid is flammable.

There is therefore a need in the art for a simple preparation method that allows for production of crystallized cobalt (II) chloride hexahydrate via a simple and cost-effective route that reduces the amount of material and energy required for the production of cobalt (II) chloride hexahydrate.

### SUMMARY

This summary is intended to provide an overview of the subject matter of this patent, and is not intended to identify essential elements or key elements of the subject matter, nor is it intended to be used to determine the scope of the claimed implementations. The proper scope of this patent may be ascertained from the claims set forth below in view of the detailed description below and the drawings.

In one general aspect, the present disclosure describes a method for production of crystallized cobalt (II) chloride hexahydrate. The method may include one or more of the following steps: preparing a first cobalt (II) chloride solution, separating impurities from the first cobalt (II) chloride solution in order to obtain a second cobalt (II) chloride solution, concentrating the second cobalt (II) chloride solution, cooling the concentrated second cobalt (II) chloride solution down to a predetermined temperature, and injecting CO₂ gas into the cooled concentrated second cobalt (II) chloride solution at an atmospheric pressure in order for cobalt (II) chloride hexahydrate crystals to form in the cooled concentrated second cobalt (II) chloride solution.

The above general aspect may include one or more of the following features. The method for production of crystallized cobalt (II) chloride hexahydrate may further include a step of separating the formed cobalt (II) chloride hexahydrate crystals from the cooled concentrated second cobalt (II) chloride solution at the predetermined temperature. According to one implementation, the predetermined temperature is in a range of about −15° C. to about −20° C.

According to one implementation, separating the formed cobalt (II) chloride hexahydrate crystals may include filtering the cooled concentrated second cobalt (II) chloride solution at the predetermined temperature.

According to one implementation, preparing a first cobalt (II) chloride solution includes dissolving cobalt oxide in a heated HCl solution. According to one implementation, separating impurities from the first cobalt (II) chloride solution includes filtering the first cobalt (II) chloride solution.

According to some implementations, concentrating the second cobalt (II) chloride solution may include heating the second cobalt (II) chloride solution in order to evaporate excess water and acid.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIG. 1 illustrates an implementation of a method for production of crystallized cobalt (II) chloride hexahydrate according to one or more aspects of the present disclosure;

FIG. 2 shows an X-ray diffraction (XRD) pattern of a CoCl₂.6H₂O sample, according to one implementation of the present disclosure.

FIG. 3 shows Fourier-transform infrared (FT-IR) spectrum of a CoCl₂.6H₂O sample, according to one implementation of the present disclosure.

### DETAILED DESCRIPTION

In the following detailed description, numerous specific details are set forth by way of examples in order to provide a thorough understanding of the relevant teachings. However, it should be apparent that the present teachings may be practiced without such details. In other instances, well known methods, procedures, components, and/or circuitry have been described at a relatively high-level, without detail, in order to avoid unnecessarily obscuring aspects of the present teachings.

Disclosed herein is a method for production of cobalt (II) chloride hexahydrate via a simple precipitation method that allows for production of highly pure cobalt (II) chloride hexahydrate from impure cobalt (II) oxide sources.

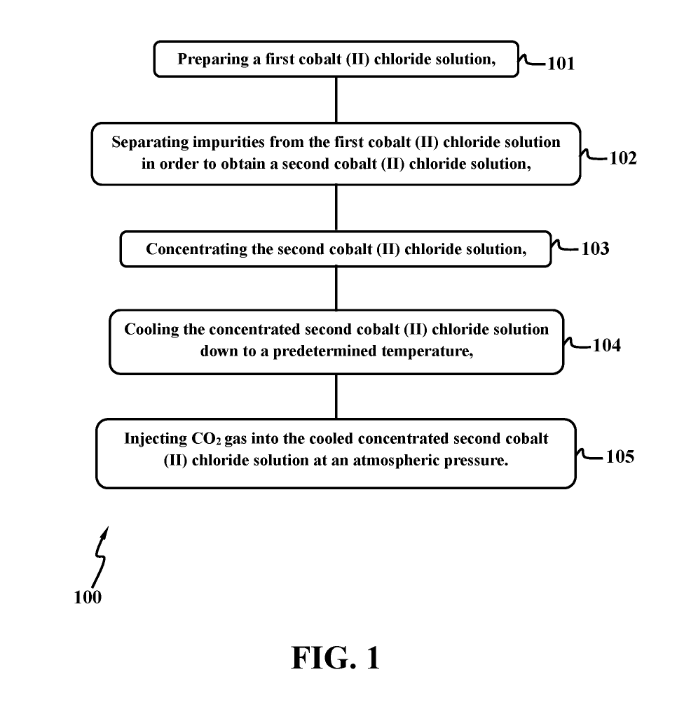

FIG. 1 illustrates a method 100 for production of crystallized Cobalt (II) chloride hexahydrate according to one or more aspects of the present disclosure. In one implementation, the method 100 may include a first step 101 of preparing a first cobalt (II) chloride solution; an optional second step 102 of separating impurities from the first cobalt (II) chloride solution in order to obtain a second cobalt (II) chloride solution; a third step 103 of concentrating the second cobalt (II) chloride solution; a fourth step 104 of cooling the concentrated second cobalt (II) chloride solution down to a predetermined temperature; and a fifth step 105 of forming Cobalt (II) Chloride hexahydrate crystals in the cooled concentrated second cobalt (II) chloride solution, for example, by injecting CO₂ gas into the cooled concentrated second cobalt (II) chloride solution at an atmospheric pressure.

Referring to FIG. 1, the first step 101 may involve dissolving cobalt oxide in a heated hydrochloric acid (HCl) solution. For example, according to some implementations, cobalt(II) oxide or cobalt monoxide powders may be dispersed in a concentrated HCl solution in water and then be heated up for a predetermined amount of time in order to obtain the first cobalt (II) chloride solution.

Referring to FIG. 1, in some implementations, in the step 102 of method 100, impurities of the first cobalt (II) chloride solution may be separated by filtering the first cobalt (II) chloride solution using a filter paper in order to obtain the second cobalt (II) chloride solution.

With respect to the third step 103, according to one implementation, the second cobalt (II) chloride solution may be concentrated by subjecting the second cobalt (II) chloride solution to continuous heating in order to evaporate the water and reduce the volume of the second cobalt (II) chloride solution.

Referring now to the fourth step 104, in an implementation, the concentrated second cobalt (II) chloride solution may be cooled down to a predetermined temperature. For example, in one implementation, the concentrated second cobalt (II) chloride solution may be cooled down to a temperature in a range of −15° C. to −20° C.

With respect to the fifth step 105, in an exemplary implementation, CO₂ gas may be injected into the cooled concentrated second cobalt (II) chloride solution at an atmospheric pressure in order for cobalt (II) chloride hexahydrate crystals to form in the cooled concentrated second cobalt (II) chloride solution. For example, in one implementation, a stream of CO₂ gas may be injected into the cobalt (II) chloride solution at a pressure of approximately 690-700 mmHg for a predetermined amount of time for dark purple crystals to form and grow in the cobalt (II) chloride solution. For example, in one implementation, the stream of CO₂ gas may be injected into the cobalt (II) chloride solution for 5 to 10 minutes. It should be understood that the injection of CO₂ gas may be carried out for other predetermined durations in other implementations. In some cases, the cobalt (II) chloride hexahydrate crystals that are formed in the cooled concentrated second cobalt (II) chloride solution may further be separated from the cooled concentrated second cobalt (II) chloride solution and dried in order to obtain the final product.

### Example 1: Production of Crystallized Cobalt (II) Chloride Hexahydrate

In this first example, crystallized cobalt (II) chloride hexahydrate was produced according to the exemplary method of FIG. 1. To this end, 10 g of cobalt (II) oxide powder was dispersed in a container that included 24-30 ml of a 1:1 (v/v) solution of concentrated hydrochloric acid in water. The concentrated hydrochloric acid had a concentration of 37%. The container was then heated up to a temperature of 70-80° C. and was kept at this temperature for 30 minutes. The solution was then filtered by a filter paper. The filtrate was then subjected to a continuous heating such that the volume of the filtrate was reduced to 8-10 ml and thereby the filtrate was concentrated, such that Co²⁺ ions had a concentration of about 7-9 molar in the concentrated filtrate. In order to crystallize the concentrated filtrate, a stream of CO₂ gas was injected into the filtrate at a temperature of −15 to −20° C. at a pressure of 690-700 mmHg for a duration of about 5-10 minutes. During this time, dark purple crystals of cobalt (II) chloride start to form and grow in the concentrated filtrate. The crystals may then be separated from the concentrated solution and be dried. In this example, about 16-18 g of crystallized cobalt (II) chloride hexahydrate (CoCl₂.6H₂O) was obtained which is referred to hereinafter as the CoCl₂.6H₂O sample.

### Example 2: Characterization Tests

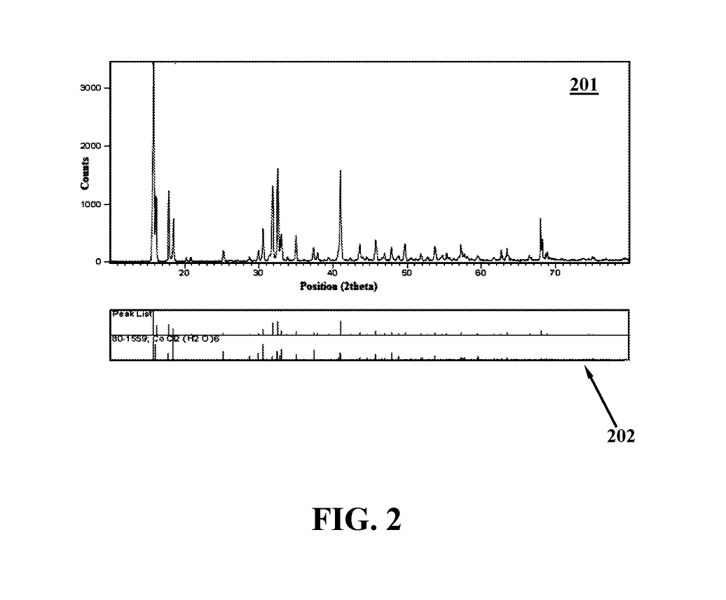

A structural analysis was carried out on the CoCl₂.6H₂O sample which was produced as described in EXAMPLE 1, using a Rigaku D-max C III, X-ray diffractometer that was operated at 40 kV and 20 mA using a Cu K-alpha (k=1.5418 Å) radiation source. The XRD data for indexing and cell-parameter were collected in an incident radiation angle of 10 to 80°. FIG. 2 shows an XRD pattern 202 of the CoCl₂.6H₂O sample along with a standard XRD pattern 201 of CoCl₂.6H₂O according to JCPDS 80-1559. Referring to FIG. 2, characteristic diffractions of CoCl₂.6H₂O as shown in the standard XRD pattern 201 have appeared in the XRD pattern 202 of the CoCl₂.6H₂O sample at 20 equal to 15.79°, 16.21°, 17.88°, 18.49°, 30.57°, 31.88°, 32.58°, 41.01° and 68.06°, which confirms the structure of the CoCl₂.6H₂O sample. The CoCl₂.6H₂O sample has grown in a monoclinic crystal system which matches JCPDS 80-1559.

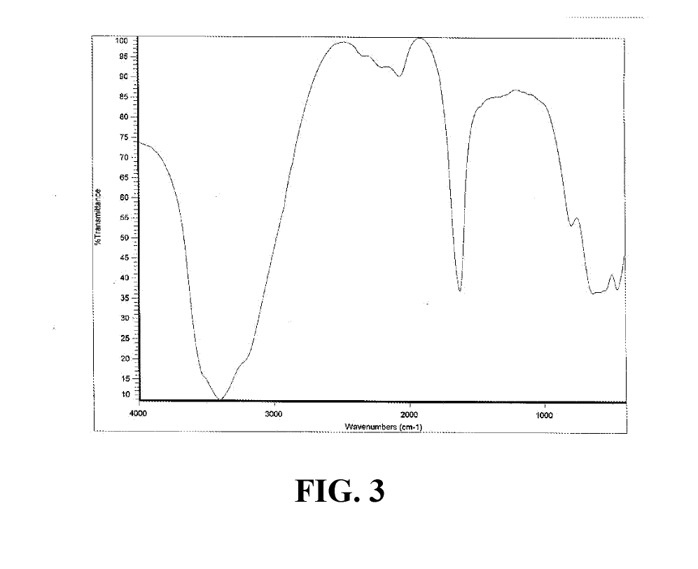

FIG. 3 shows FT-IR spectrum of CoCl₂.6H₂O sample, according to one implementation of the present disclosure. Spectroscopic analysis of the samples was carried out using Shimadzu Varian 4300 FTIR spectrophotometer in KBr pellets in the range of 4000-400 cm⁻¹. Referring to FIG. 3, in the spectrum, there are several sharp peaks at around 3401, 1624, 810, 640, 582 and 458 cm⁻¹. The absorption bands below 1000 cm⁻¹ originate from the vibrational modes of transition metal-oxygen (M-O) stretching vibration modes. In addition, asymmetric stretching vibration of CoCl₂ linear molecules can be observed in this region. A strong and broad absorption centered at the 3401 cm⁻¹ is due to stretching mode of water hydroxyl group (n O—H). The absorption band at around 1624 cm⁻¹ is due to the bending vibration mode (ν₂) of adsorbed water on the surface of the material.

The chemical composition of the CoCl₂.6H₂O sample was determined by X-ray fluorescence (XRF) analysis. Semi-quantitative results of the XRF analysis showed that the CoCl₂.6H₂O sample contained 42.686% cobalt and 48.299% Chlorine. The CoCl₂.6H₂O sample further included trace amounts of S, Fe, Ni and Ba.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

The scope of protection is limited solely by the claims that now follow. That scope is intended and should be interpreted to be as broad as is consistent with the ordinary meaning of the language that is used in the claims when interpreted in light of this specification and the prosecution history that follows and to encompass all structural and functional equivalents. Notwithstanding, none of the claims are intended to embrace subject matter that fails to satisfy the requirement of Sections 101, 102, or 103 of the Patent Act, nor should they be interpreted in such a way. Any unintended embracement of such subject matter is hereby disclaimed.

Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. In addition, in the foregoing Detailed Description, it can be seen that various features are grouped together in various implementations. This is for purposes of streamlining the disclosure, and is not to be interpreted as reflecting an intention that the claimed implementations require more features than are expressly recited in each claim. Rather, as the following claims reflect, inventive subject matter lies in less than all features of a single disclosed implementation. Thus, the following claims are hereby incorporated into the Detailed Description, with each claim standing on its own as a separately claimed subject matter.

While various implementations have been described, the description is intended to be exemplary, rather than limiting and it will be apparent to those of ordinary skill in the art that many more implementations and implementations are possible that are within the scope of the implementations. Although many possible combinations of features are shown in the accompanying figures and discussed in this detailed description, many other combinations of the disclosed features are possible. Any feature of any implementation may be used in combination with or substituted for any other feature or element in any other implementation unless specifically restricted. Therefore, it will be understood that any of the features shown and/or discussed in the present disclosure may be implemented together in any suitable combination. Accordingly, the implementations are not to be restricted except in light of the attached claims and their equivalents. Also, various modifications and changes may be made within the scope of the attached claims.

What is claimed is:

1. A method for production of crystallized Cobalt (II) Chloride hexahydrate, the method comprising:
preparing a first cobalt (II) chloride solution;
separating impurities from the first cobalt (II) chloride solution to obtain a second cobalt (II) chloride solution;
concentrating the second cobalt (II) chloride solution to a concentrated second cobalt (II) chloride solution;
cooling the concentrated second cobalt (II) chloride solution to a cooled concentrated second cobalt (II) chloride solution; and
forming Cobalt (II) Chloride hexahydrate crystals in the cooled concentrated second cobalt (II) chloride solution, wherein the forming includes injecting CO₂ gas into the cooled concentrated second cobalt (II) chloride solution at an atmospheric pressure.

2. The method according to claim 1, wherein cooling the concentrated second cobalt (II) chloride solution to the cooled concentrated second cobalt (II) chloride solution includes cooling the concentrated second cobalt (II) chloride solution to a predetermined temperature.

3. The method according to claim 2, wherein the method further includes separating the formed Cobalt (II) Chloride hexahydrate crystals from the cooled concentrated second cobalt (II) chloride solution at the predetermined temperature.

4. The method according to claim 3, wherein separating the formed Cobalt (II) Chloride hexahydrate crystals includes filtering the cooled concentrated second cobalt (II) chloride solution at the predetermined temperature.

5. The method according to claim 4, wherein the filtering includes filtering through a filter paper.

6. The method according to claim 1, wherein preparing the first cobalt (II) chloride solution includes dissolving cobalt oxide in a heated hydrochloric acid (HCl) solution.

7. The method according to claim 1, wherein preparing the first cobalt (II) chloride solution includes:
dispersing cobalt monoxide powders in a concentrated hydrochloric acid (HCl) solution, the concentrated HCl solution being in water, and
obtaining the first cobalt (II) chloride solution by heating the concentrated HCl solution with dispersed cobalt monoxide powders for a predetermined amount of time.

8. The method according to claim 1, wherein separating impurities from the first cobalt (II) chloride solution includes filtering the first cobalt (II) chloride solution.

9. The method according to claim 1, wherein concentrating the second cobalt (II) chloride solution includes evaporating excess water and acid.

10. The method according to claim 9, wherein evaporating excess water and acid includes heating the second cobalt (II) chloride solution.

11. The method according to claim 1, wherein the predetermined temperature is in a range of about −15° C. to about −20° C.

12. The method according to claim 1, wherein preparing the first cobalt (II) chloride solution includes, in a container:
dispersing cobalt (II) oxide powder in a 1:1 (v/v) solution of concentrated hydrochloric acid (HCl) in water, and
heating the container to a temperature of 70-80° C., and
wherein separating impurities from the first cobalt (II) chloride solution to obtain the second cobalt (II) chloride includes filtering the solution by a filter paper, to obtain a filtrate, the filtrate being the second cobalt (II) chloride solution.

13. The method according to claim 12, wherein concentrating the second cobalt (II) chloride solution to the concentrated second cobalt (II) chloride solution includes:
continuously heating the filtrate to form a concentrated filtrate, the concentrated filtrate being the concentrated second cobalt (II) chloride solution, wherein the continuously heating is configured to reduce the volume of the filtrate such that Co²⁺ ions have a concentration of about 7-9 molar.

14. The method according to claim 13, wherein:
forming Cobalt (II) Chloride hexahydrate crystals includes crystallizing the concentrated filtrate,
crystallizing the concentrated filtrate includes injecting a stream of carbon dioxide (CO₂) gas into the concentrated filtrate.

15. The method according to claim 14, wherein:
injecting the stream of CO₂ gas into the concentrated filtrate includes injecting the CO₂ at a temperature of −15 to −20° C. at a pressure of 690-700 mmHg for a duration of about 5-10 minutes.
